(19) United States
(12) Patent Application Publication
(10) Pub. No.: US 2014/0035132 A1
(43) Pub. Date: Feb. 6, 2014

(54) SURFACE MOUNT CHIP

(71) Applicants: Universite Francois Rabelais, Tours Cedex (FR); STMicroelectronics (Tours) SAS, Tours (FR)

(72) Inventors: Olivier Ory, Tours (FR); Cedric Le Coq, St-Cyr Sur Loire (FR)

(73) Assignees: Universite Francois Rabelais, Tours Cedex (FR); STMicroelectronics (Tours) SAS, Tours (FR)

(21) Appl. No.: 13/955,325

(22) Filed: Jul. 31, 2013

(30) Foreign Application Priority Data
Aug. 2, 2012 (FR) 12/57536

(51) Int. Cl. H01L 23/00

(52) U.S. Cl. CPC H01L 24/01; H01L 24/10
USPC 257/737; 257/778

(57) ABSTRACT

A surface mount chip including, on the side of a surface, first and second pads of connection to an external device, wherein, in top view, the first pad has an elongated general shape, and the second pad is a point-shaped pad which is not aligned with the first pad.

### CROSS REFERENCE TO RELATED APPLICATIONS

This application claims the priority benefit of French patent application serial number 12/57536, filed on Aug. 2, 2012, which is hereby incorporated by reference to the maximum extent allowable by law.

### BACKGROUND

1. Technical Field

The present disclosure relates to the field of electronic chips. It more specifically aims at surface mount (or flip-chip) chips, that is, chips comprising, on the side of at least one surface, electric connection pads intended to be directly soldered to contact areas of an external device such as a printed circuit board or another chip.

2. Discussion of the Related Art

FIGS. 1A and 1B schematically show a surface mount chip 100. FIG. 1A is a top view, and FIG. 1B is a cross-section view along plane B-B of FIG. 1A. Chip 100 comprises a substrate 101, for example, a semiconductor substrate, inside and on top of which are formed one or several electronic components (not shown). On one side of a surface (the upper surface in the shown example,), chip 100 comprises electric connection pads 103 (four pads in the present example) intended to be directly soldered to contact areas of an external device (not shown). Each pad 103 comprises a metallization 105, for example, having a circular shape (in top view), and a connection element 107 such as a solder bump or a solidified solder drop, coating metallization 105.

When assembled in an external device, the chip is positioned so that connection elements 107 bear against corresponding contact areas of the external device. The assembly is then heated beyond the melting point of connection elements 107 to perform the soldering.

Some flip-chip assembled chips, for example, some discrete component chips or some microbattery chips, only comprise two pads of electric connection on the side of their surface of connection to an external device.

FIGS. 2A to 2C schematically show a surface mount chip 200 only comprising two electric connection pads 203 on the side of its surface of connection to an external device (upper surface in the shown example). FIG. 2A is a top view, and FIGS. 2B and 2C are cross-section views, respectively along planes B-B and C-C of FIG. 2A.

For mechanical stability reasons, pads 203 are not point-shaped pads of the type described in relation with FIG. 1, but have an elongated shape (in top view). Each of pads 203 comprises a metallization 205 of elongated shape, formed on the upper surface side of substrate 101, and an elongated connection element 207 coating metallization 205. As an example, metallization 205 comprises two circular lands connected by a conductive strip, and connection element 207 is formed from two solder bumps or two drops of solder paste respectively arranged on the two circular lands. After anneal, the solder material spreads on the entire surface of metallization 205, and connection element 207 takes an elongated shape comprising a substantially rectilinear upper edge.

In the shown example, chip 200 has, in top view, a generally rectangular shape. Pads 203 are arranged parallel to the shortest chip edges, respectively close to the two opposite short chip edges. The length of pads 203 is of the same order of magnitude as the length of the short chip edges.

Chip 200 of FIG. 2 has the advantage of being able to be in a position of equilibrium on its connection pads 203 when flipped, which makes its assembly in an external device easier. It should in particular be noted that if pads 203 were point-shaped pads of the type described in relation with FIG. 1, the chip could not be stable on two pads only. This would make chip-assembly handling operations in an external device particularly delicate. This would further result in a relatively fragile assembly, and thus in an unreliable final device.

The use of elongated pads, however, has the disadvantage that the pads take up, in top view, a surface area greater than that taken up by point-shaped pads of the type described in relation with FIG. 1. This all the more decreases the substrate surface area available to form components. This further increases stray capacitances between the pads and the substrate.

### SUMMARY

An embodiment provides a surface mount chip only comprising two contact pads on the side of a surface of connection to an external device, this chip at least partly overcoming some of the disadvantages of existing chips.

Thus, an embodiment provides a surface mount chip comprising, on the side of a surface, first and second pads of connection to an external device, wherein, in top view, the first pad has an elongated general shape, and the second pad is a point-shaped pad which is not aligned with the first pad.

According to an embodiment, in top view, the largest dimension of the first pad is greater by at least a factor 2 than that of the second pad.

According to an embodiment, the chip has, in top view, a rectangular general shape.

According to an embodiment, the first pad is substantially parallel to the two shortest chip edges.

According to an embodiment, the second pad is approximately equidistant from the two longest chip edges.

According to an embodiment, in top view, the largest dimension of the first pad is at least equal to half the smallest width of the chip.

According to an embodiment, in top view, the largest dimension of the second pad is smaller than 10 percent of the smallest width of the chip.

According to an embodiment, in top view, the smallest width of the rectangle circumscribed in the first pad is substantially equal to the largest dimension of the second pad.

According to an embodiment, the first pad comprises two conductive bumps or drops interconnected by a conductive strip.

According to an embodiment, the second pad comprises a conductive bump or drop.

The foregoing and other features and advantages will be discussed in detail in the following non-limiting description of specific embodiments in connection with the accompanying drawings.

### BRIEF DESCRIPTION OF THE DRAWINGS

FIGS. 1A and 1B, previously described, are top and cross-section views schematically showing an example of a surface mount chip;

FIGS. 2A to 2C, previously described, are top and cross-section views schematically showing another example of a surface mount chip;

FIG. 3 is a top view schematically showing an embodiment of a surface mount chip;

FIG. 4 is a top view schematically showing an alternative embodiment of a surface mount chip; and

FIGS. 5A to 5C are top and cross-section views schematically showing another alternative embodiment of a surface mount chip.

For clarity, the same elements have been designated with the same reference numerals in the different drawings and, further, as usual in the representation of electronic chips, the various drawings are not to scale.

### DETAILED DESCRIPTION

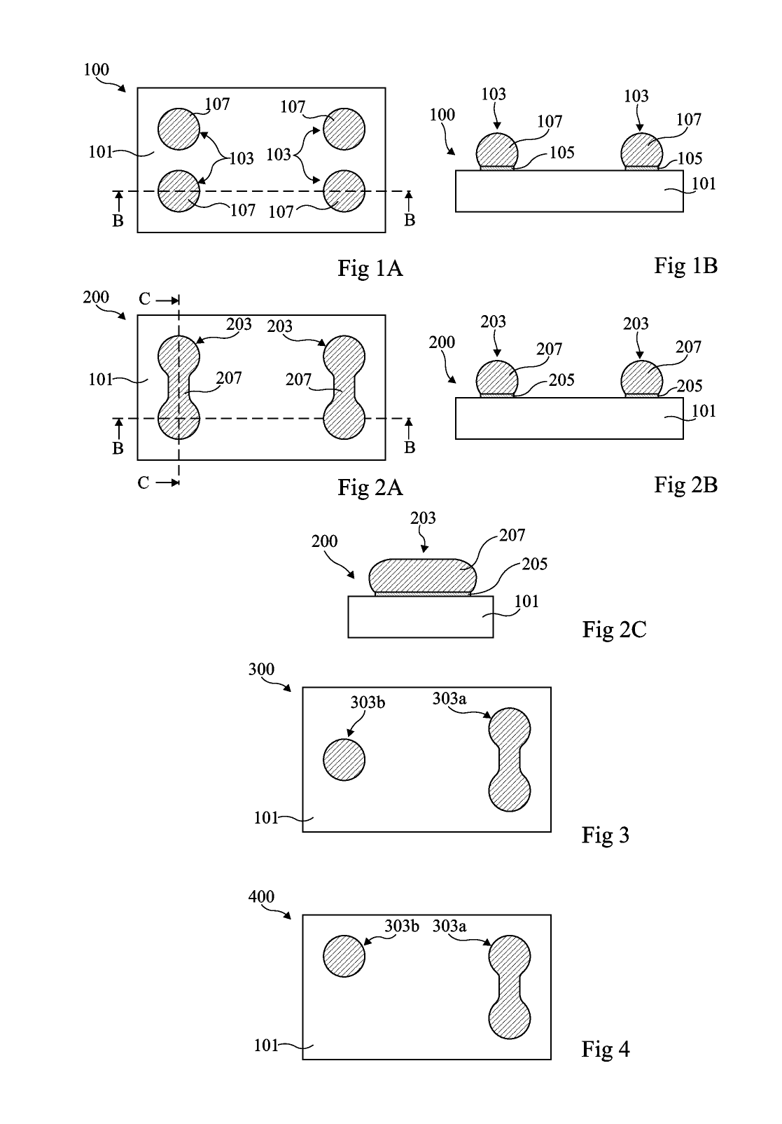

FIG. 3 is a top view schematically showing an embodiment of a surface mount chip. Chip 300 of FIG. 3 comprises a substrate 101, for example, a semiconductor substrate, inside and on top of which one or several electronic components (not shown) may be formed. On one side of a surface (the upper surface in the present example,), chip 300 comprises two electric connection pads 303a and 303b intended to be directly soldered to contact areas of an external device (not shown). First pad 303a is an elongated pad, for example, a pad of the type described in relation with FIGS. 2A to 2C, and second pad 303b is a point-shaped pad, for example, a pad of the type described in relation with FIGS. 1A and 1B.

In the shown example, chip 300 has, in top view, an approximately rectangular shape, and pads 303a and 303b are respectively arranged close to the two shortest chip edges. In this example, elongated pad 303a is arranged parallel to the short chip edges, that is, in top view, its largest dimension is parallel to the short chip edges, and point-shaped pad 303b is approximately arranged to be equidistant from the two longest chip edges.

The combination of an elongated pad with a point-shaped pad enables, on the one hand, chip 300 to be in a stable position of equilibrium on its connection pads when flipped, since pads 303a and 303b respectively define a rectilinear supporting edge or strip, and a support point which is not aligned with the edge and, on the other hand, to decrease the surface area occupied by the pads with respect to a chip with two elongated pads of the type described in relation with FIG. 2. The support stability provided by pads 303a and 303b ascertains an easy assembly of the chip in an external device, as well as a good mechanical resistance of the assembly. The decrease of the surface area occupied by the pads increases the substrate surface area available to form components, and limits stray capacitances between the pads and the substrate. Another advantage of chip 300 is that the shape difference between pad 303a and pad 303b enables to easily differentiate two pads, and to avoid component biasing errors.

As an example, the solder bumps or drops used to form the connection elements of pads 303a and 303b have a diameter approximately ranging between 75 and 150 μm, and the length of elongated pad 303a approximately ranges between 200 and 350 μm.

It will be within the abilities of those skilled in the art to provide other arrangements of elongated pad 303a and of point-shaped pad 303b, providing the above-mentioned advantages. This enables to take into account constraints regarding the placing of the chip components and/or constraints regarding the placing of the connection areas of the external device. For example, elongated pad 303a may be oriented along a direction non-parallel to an edge of the chip. To obtain the desired mechanical stability effect, it will however be ascertained that the elongated pad is not aligned with the point-shaped pad, that is, in top view, the largest dimension of the elongated pad is oriented along a direction which does not cross the point-shaped pad.

Further, elongated pad 303a and point-shaped pad 303b may have other shapes than those described in relation with FIG. 3. Generally, in the context of the present description, point-shaped pad designates any pad such that when the chip is flipped and the pad rests on a planar surface (before soldering of the pad to a contact area of an external device), the contact region between the pad and this planar surface is a point or almost a point, that is, its largest dimension is negligible as compared with the chip dimensions, for example, smaller than 10 percent of the smallest width of the chip. In a preferred embodiment, in top view, the largest dimension of pad 303b is smaller than 10 percent of the smallest width of the chip. Further, “elongated pad” here means any pad such that, when the chip is flipped and the pad rests on a planar surface (before soldering of the pads to contact areas of an external device), the contact region between the pad and this planar surface is not a point, that is, it comprises at least two points separated by a non-negligible distance as compared with the chip dimensions, for example, a distance greater than 50 percent of the smallest width of the chip. In preferred embodiment, in top view, the largest dimension of pad 303a is greater than 50 percent of the smallest width of the chip. In top view, the largest dimension of elongated pad 303a is preferably greater by at least a factor 2 than the largest dimension of point-shaped pad 303b. Further, the smallest width of the rectangle circumscribed in elongated pad 303a is preferably substantially equal to the largest dimension of point-shaped pad 303b. Further, in top view, the largest width of the rectangle circumscribed in elongated pad 303a is preferably at least twice as large as the smallest width of this same rectangle.

FIG. 4 is a top view schematically showing an alternative embodiment of a surface mount chip. Chip 400 of FIG. 4 comprises the same elements as chip 300 of FIG. 3, but differs from chip 300 in that point-shaped pad 303b is not equidistant from the two longest chip edges, but is located close to a corner of the chip.

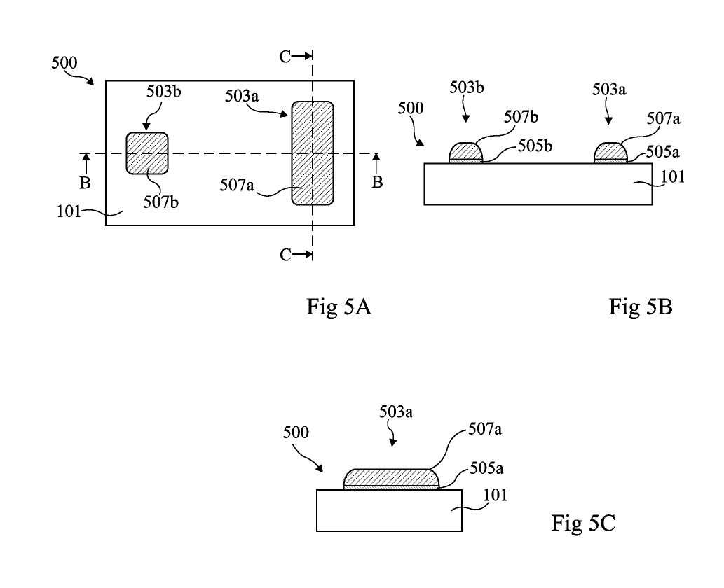

FIGS. 5A to 5C schematically show another alternative embodiment of a surface mount chip. FIG. 5A is a top view, and FIGS. 5B and 5C are cross-section views, respectively along planes B-B and C-C of FIG. 5A. Chip 500 of FIGS. 5A to 5C differs from chip 300 of FIG. 3 essentially by the forming of its electric connection pads. Chip 500 comprises an elongated pad 503a and a point-shaped pad 503b, arranged substantially at the same positions on the chip as elongated pad 303a and point-shaped pad 303b of chip 300 of FIG. 3. Pads 503a and 503b each comprise a metallization, respectively 505a, 505b, formed on the side of the upper surface of substrate 101. As an example, in top view, metallization 505a has the shape of a rectangular strip portion, and metallization 505b has an approximately square shape with side length equal to the smallest width of metallization 503a. Metallizations 505a and 505b are each coated with a connection element, respectively 507a, 507b. Connection elements 507a and 507b are directly made in the form of a layer coating the entire surface of the metallizations, for example, by local electrodeposition of a solder material, or by deposition of solder paste through a sieve.

Specific embodiments of the present invention have been described. Various alterations, modifications, and improvements will readily occur to those skilled in the art. In particular, to reinforce the mechanical strength and decrease short-circuit risks on assembly of the chip in an external device, it may be provided to partially embed the chip connection pads in a protection resin layer covering the entire upper chip surface across a thickness slightly smaller than the height of the pads. As a complement or as a variation, a protection resin layer may also be provided on the side of the chip which comprises no pads of connection to an external device, as well as on the chip sides.

Various embodiments with different variations have been described hereabove. It should be noted that those skilled in the art may combine various elements of these various embodiments and variations without showing any inventive step.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A surface mount chip comprising, on the side of a surface, only two pads, a first pad having an elongated shape, and a second point-shaped pad.

2. The chip of claim 1, wherein, in top view, the largest dimension of the first pad is greater by at least a factor 2 than that of the second pad.

3. The chip of claim 1 having, in top view, a rectangular general shape.

4. The chip of claim 3, wherein the first pad is substantially parallel to the two shortest chip edges.

5. The chip of claim 3, wherein the second pad is approximately equidistant from the two longest chip edges.

6. The chip of claim 1, wherein, in top view, the largest dimension of the first pad is at least equal to half the smallest width of the chip.

7. The chip of claim 1, wherein, in top view, the largest dimension of the second pad is smaller than 10 percent of the smallest width of the chip.

8. The chip of claim 1, wherein, in top view, the smallest width of the rectangle circumscribed in the first pad is substantially equal to the largest dimension of the second pad.

9. The chip of claim 1, wherein the first pad comprises two conductive bumps or drops interconnected by a conductive strip.

10. The chip of claim 1, wherein the second pad comprises a conductive bump or drop.
